(19) United States
(12) Patent Application Publication
(10) Pub. No.: US 2008/0268381 A1
(43) Pub. Date: Oct. 30, 2008

(54) Pattern forming method performing multiple exposure so that total amount of exposure exceeds threshold

(75) Inventors: Masayoshi Saito, Tokyo (JP); Shinji Ohara, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: ELPIDA MEMORY, INC., Tokyo (JP)

(21) Appl. No.: 12/081,765

(22) Filed: Apr. 21, 2008

(30) Foreign Application Priority Data
Apr. 25, 2007 (JP) 2007-115410

(51) Int. Cl. G03F 7/20

(52) U.S. Cl. 430/323

(57) ABSTRACT

A pattern forming method includes forming a resist film on a target film to be processed, which is formed on a substrate; and forming a basic pattern part in the resist film by multiple exposure using photomasks, wherein each exposure process is performed at an amount of exposure smaller than a threshold assigned to the resist film; and the resist film is developed after the total sum of the amounts of exposure through a plurality of exposure processes exceeds the threshold, so that the basic pattern part including a hole shape, which corresponds to each area where the total amount of exposure through the exposure processes via the photomasks exceeds the threshold, is formed in the resist film. The method also includes performing etching via the basic pattern part so as to form a desired pattern in the target film.

### BACKGROUND OF THE INVENTION

1. Field of the Invention

The present invention relates to a pattern forming method for forming a fine hole or line pattern on a film to be processed with a high resolution.

Priority is claimed on Japanese Patent Application No. 2007-115410, filed Apr. 25, 2007, the contents of which are incorporated herein by reference.

2. Description of the Related Art

In recent years, a large-scale integrated circuit (LSI) in which a large number of MOS transistors, resistors, capacitors, and the like are integrated on a single chip is employed in a main part of a computer or an electric device. In a device such as DRAM (dynamic random access memory) among LSIs, fine patterning has been rapidly developed, and accordingly, wiring lines or contact holes with respect to MOS transistors or registers have been reduced in size almost to the limit of the exposure techniques used.

As a technique for forming such a fine wiring pattern, Japanese Unexamined Patent Application, First Publication No. 2002-031884 discloses a method having a step of forming a photoresist film on a semiconductor substrate, and transferring a first mask pattern to the photoresist film by means of exposure, and a step of superimposing a second mask pattern on the first mask pattern by further transferring the second mask pattern to the photoresist film by means of multiple exposure.

In another known technique disclosed by Japanese Unexamined Patent Application, First Publication No. 2005-129688, a photoresist film and a mask film are deposited on a wafer, and the wafer is subjected to reduced-projection exposure so that a first transfer area and a second transfer area of the relevant mask are transferred to a single area in a superimposed form, wherein a half-tone film is provided at each of the first and second transfer areas, and in pattern exposure, the phase of the pattern is inversed for each area.

Japanese Unexamined Patent Application, First Publication No. 2001-110719 discloses a method of forming a single contact-hole pattern by subjecting two divided pattern parts to double exposure, and also a method of forming a divided pattern part consisting of a Levenson phase-shift mask pattern in each divided area, so as to perform multiple exposure by means of scanning exposure.

However, in the known exposure techniques, a circular contact-hole pattern is formed on a photoresist even when performing reduced-projection exposure by using a photomask, such as a reticle, having a four-corner (i.e., square or rectangular) contact-hole pattern. That is, when forming a fine contact hole corresponding to almost limit resolution, the presently-known photoresist technique employing reduced-projection exposure causes (i) a first problem in which the diameter of the formed contact-hole pattern varies from a desired value, and (ii) a second problem in which the focus margin is small, that is, the range having an appropriate exposure condition is limited. In particular, with respect to each corner part of a four-corner contact-hole pattern, light diffuses due to diffraction of light at the sides which form the corner, so that the fine contact hole, anticipated to have a four-corner form, has a circular section.

Therefore, even when each contact-hole pattern obtained by the known exposure techniques has a four-corner form in the design process, it tends to finally obtain a circular sectional shape. Therefore, in a contact plug formed by embedding a conductive material into the relevant contact hole, the area which contacts a wiring pattern having a specific width tends to have a circular pattern shape, and thus the relevant contact area is smaller than the assumed area of the four-corner pattern shape in the design process. This circumstance further causes (iii) a third problem in which the part which contacts the wiring has a high electric resistance, and (iv) a fourth problem in which electric current tends to concentrate at the part (having a circular pattern shape) which contacts the wiring, which tends to cause a degradation of the wiring.

In order to solve the above problems, for example, Published Japanese Translation, No. 2002-520875, of PCT International Publication, No. WO0004571, discloses the following exposure method.

First, as shown in FIG. 31, a target film 101 to be processed, which may be made of silicon oxide, is deposited on a substrate 100, and a mask film 102, which may be made of silicon nitride, is stacked thereon. A line pattern 103 using a resist film is further formed thereon. Next, the mask film 102 under the line pattern 103 is subjected to etching by means of the line pattern 103, so as to process the mask film 102 to have a line shape, thereby forming a line pattern 105 (see FIG. 32). The resist film 103 is then removed.

In the next step, after a resist film (not shown) is again deposited, exposure is performed by using a photomask which has a pattern formed perpendicularly to the line pattern 103 shown in FIG. 31, so as to form a plurality of resist patterns 106 (see FIG. 33) perpendicular to the line pattern 105. The target film 101 is then subjected to etching using the resist patterns 106 and the above line pattern 105 as a mask, so that a pattern 108 (of the target film), which includes hole parts 107 at the periphery, is formed on the substrate 100, and the resist film used in this process is removed.

Finally, the line pattern 105 is removed, thereby forming the plurality of the hole parts 107, as shown in FIG. 35.

However, when the hole pattern is formed by using the above-described method, another problem occurs as explained below.

In the method explained with reference to FIGS. 31 to 35, superimposition of line patterns is performed by means of double exposure. Therefore, after the mask film 102 (see FIG. 31) is formed and processed, it is necessary to remove the resist film 103 and then again deposit a resist film so as to perform exposure for forming the resist patterns 106. In addition, as shown in FIG. 34, if the mask film 105 remains, it damages flatness of the surface of the target film 101, and affects the subsequent processes. Therefore, it is necessary to finally remove the mask film 105 (i.e., line pattern), as shown in FIG. 35.

Therefore, the method explained with reference to FIGS. 31 to 35 has lots of processes required for processing, and is thus complex.

### SUMMARY OF THE INVENTION

In light of the above circumstances, an object of the present invention is to provide a pattern forming technique employing an easy manufacturing method including a very small number of processes, in which even when a fine four-corner pattern having a width close to a limit resolution is formed by utilizing the advantage of double exposure, a circular patter is hardly produced, and a pattern closer to a four-corner shape can be formed in comparison with the conventional techniques, that is, a fine pattern inconformity with a desired shape can be formed very easily at low cost, without providing an irregular shape.

Another object of the present invention is to provide a pattern forming technique by which even when forming fine patterns, the interval between the patterns can be reduced so as to provide a high density arrangement, and to form the patterns with a narrower pitch in comparison with the possible interval in the conventional techniques.

Another object of the present invention is to provide a pattern forming technique by which even when forming fine patterns, the dimensional accuracy with respect to pattern formation is high, so that electric resistance at each formed part to be connected to wiring can be low, thereby preventing the wiring from being degraded due to electric current concentration.

Therefore, the present invention provides a first pattern forming method comprising the steps of:

forming a resist film on a target film to be processed, which is formed on a substrate;

forming a basic pattern part in the resist film by multiple exposure using photomasks, wherein:
each exposure process is performed at an amount of exposure smaller than a threshold assigned to the resist film; and
the resist film is developed after the total sum of the amounts of exposure through a plurality of exposure processes exceeds the threshold, so that the basic pattern part including a hole shape, which corresponds to each area where the total amount of exposure through the exposure processes via the photomasks exceeds the threshold, is formed in the resist film; and

performing etching via the basic pattern part so as to form a desired pattern in the target film.

The present invention also provides a second pattern forming method comprising the steps of:

sequentially forming a mask film and a resist film on a target film to be processed, which is formed on a substrate;

forming a basic pattern part in the resist film by multiple exposure using photomasks, wherein:
each exposure process is performed at an amount of exposure smaller than a threshold assigned to the resist film; and
the resist film is developed after the total sum of the amounts of exposure through a plurality of exposure processes exceeds the threshold, so that the basic pattern part including a hole shape, which corresponds to each area where the total amount of exposure through the exposure processes via the photomasks exceeds the threshold, is formed in the resist film;

etching the mask film via the basic pattern part so as to form the corresponding basic pattern part in the mask film;

forming a reduced pattern part by providing a side wall to the inside of a hole in the basic pattern part of the mask film so as to narrow the hole; and

etching the target film by using the reduced pattern part.

The present invention also provides a third pattern forming method comprising the steps of:

forming a resist film on a target film to be processed, which is formed on a substrate;

forming a basic pattern part in the resist film by multiple exposure using photomasks, wherein:
each exposure process is performed at an amount of exposure smaller than a threshold assigned to the resist film; and
the resist film is developed after the total sum of the amounts of exposure through a plurality of exposure processes exceeds the threshold, so that the basic pattern part including a hole shape, which corresponds to each area where the total amount of exposure through the exposure processes via the photomasks exceeds the threshold, is formed in the resist film;

forming an enlarged pattern part by partially removing the resist film so as to enlarge a hole in the basic pattern part; and

etching the target film by using the enlarged pattern part.

In a typical example of each pattern forming method:

a first exposure process is performed using a first photomask having a first pattern, where the amount of exposure is set to be smaller than the threshold assigned to the resist film; and

a second exposure process is performed using a second photomask having a second pattern, where the amount of exposure is set to be smaller than the threshold assigned to the resist film, and the total sum of the amounts of exposure through the first and second exposure processes exceeds the threshold.

In each pattern forming method, typically, the resist film is a positive resist film.

In each pattern forming method, preferably, the plurality of exposure processes use different photomasks having patterns which differ from each other, and the total sum of the amounts of exposure through the first and second exposure processes exceeds the threshold in common parts between the patterns of the photomasks.

In the third pattern forming method, preferably, when forming the enlarged pattern part, the basic pattern part is subjected to ashing so as to partially remove the basic pattern part.

In each pattern forming method, preferably, reticles to which different magnification are assigned in the vertical and horizontal directions are used as the photomasks.

In each pattern forming method, preferably, when forming the basic pattern part by multiple exposure, the scanning direction of an exposure process is set to be substantially perpendicular to that of another exposure process.

In accordance with the present invention, when forming a fine hole pattern corresponding to almost the limit resolution, it is possible to solve a problem with respect to exposure through a single projection and exposure process as performed in the conventional techniques, in which when corners of the hole pattern receive influence of optical diffraction, the exposed area is diffused more than required, and a hole pattern having corners, each of which has a vague outline, is formed. That is, it is possible to cancel the influence of the diffraction on the relevant corners and to form a hole pattern having corners, each of which has an accurate outline, by forming the hole pattern through the plurality of exposure processes using a pattern combination, in which the amount of exposure in each process is smaller than the threshold assigned to the resist film, and the total sum of the amounts of exposure through the plurality of exposure processes exceeds the threshold. In particular, in accordance with the present invention, even when forming a hole pattern having a four-corner or polygonal section at almost the limit resolution, such a hole pattern can be formed without rounding each corner.

Also when arranging hole patterns formed by a conventional single exposure, it is difficult to obtain a pitch less than a specific interval, due to the diffraction in the relevant projection and exposure process. However, in accordance with the present invention, relevant holes can be more closely arranged with a narrower pitch in comparison with the conventional techniques.

That is, in contrast with a rounded hole pattern obtained by the conventional techniques, a hole pattern having a four-corner section can be formed in the present invention. Therefore, when a conductive material is embedded into the hole pattern so as to form a connection part such as a contact plug, the contact area of the connection part can be increased, so that the relevant electric resistance can be reduced. Accordingly, it is possible to reduce current concentration on the connection part and thus to prevent the relevant wiring from degrading.

Also in accordance with the present invention, it is possible to form a reduced pattern part by providing a side wall to the inside of a hole in the basic pattern part of the mask film so as to narrow the hole; and to etch the target film by using the reduced pattern part. Therefore, the pattern size can be precisely controlled, and closely-arranged hole patterns, each having a desired size, can be provided.

In accordance with the present invention, it is also possible to form a basic pattern part in the resist film; to form an enlarged pattern part by partially removing the resist film so as to enlarge a hole in the basic pattern part; and to etch the target film by using the enlarged pattern part. Therefore, also in this case, the pattern size can be precisely controlled, and closely-arranged hole patterns, each having a desired size, can be provided.

Also in the present invention, a positive resist film can be used as the resist film. Generally, in comparison with a negative resist film, a positive resist film has a higher sensitivity, and thus it is possible to perform exposure at an approximately one-tenth amount of exposure, and also to easily increase the resolution. Therefore, in comparison with exposure using a negative resist film, it is possible to more easily form a fine pattern. Accordingly, manufacturing with respect to fine patterns can be easily performed, the throughput in the relevant production can be improved, and it is possible to prevent optical elements in the relevant exposure apparatus from being worn out, thereby reducing the production cost.

### BRIEF DESCRIPTION OF THE DRAWINGS

FIG. 1 is a sectional view showing a stacked body of a substrate and a resist film, which are used when the present invention is implemented.

FIG. 2 is a plan view showing an example of the pattern to be formed in an embodiment of the present invention.

FIG. 3 is a perspective view showing an example of the exposure apparatus used in the embodiment.

FIG. 4 is a sectional view showing a state in which a first exposure process has been applied to the resist film in the embodiment.

FIG. 5 is a diagram showing a relationship between the amount of exposure and the thickness of the resist film after the development with respect to the embodiment.

FIG. 6 is a plan view showing a state in which the first exposure process has been applied to the resist film in the embodiment.

FIG. 7 is a plan view showing a state in which a second exposure process has been applied to the resist film in the embodiment.

FIG. 8 is a sectional view along line B-B′ in FIG. 7, showing a state in which the second exposure process has been applied to the resist film in the embodiment.

FIG. 9 is a sectional view showing a state in which the object shown in FIG. 7 has been developed in the embodiment.

FIG. 10 is a diagram showing a state in which the film 2 in the object shown in FIG. 9 has been etched via the resist film in the embodiment.

FIG. 11 is a diagram showing a state in which hole parts have been formed in the resist film in the embodiment.

FIG. 12 is a diagram showing a state in which the mask film has been etched via the resist film in the embodiment.

FIG. 13 is a diagram showing a state in which the insulating film has been etched via the mask film in the embodiment.

FIG. 14 is a diagram showing a hole pattern formed in the insulating film in the embodiment.

FIG. 15 is a diagram for explaining a process for thinning a pattern formed in the resist film by means of ashing in the embodiment.

FIG. 16 is a diagram showing a state in which a pattern formed in the resist film has been thickened by attaching side walls thereto in the embodiment.

FIG. 17 is a diagram showing a state in which the resist film has been patterned in the embodiment.

FIG. 18 is a diagram showing a state in which the patterned resist film has been subjected to ashing.

FIG. 19 is a diagram showing a state in which the mask film has been etched via the resist film which was subjected to the ashing.

FIG. 20 is a diagram showing a state in which the resist film has been patterned in the embodiment.

FIG. 21 is a diagram showing a state in which the mask film has been patterned in the embodiment.

FIG. 22 is a diagram showing a state in which side walls have been attached to the patterned mask film in the embodiment.

FIGS. 23A and 23B are diagrams showing an example of contact plugs formed on a wiring line in the embodiment.

FIGS. 24A and 24B are diagrams showing another example of contact plugs formed on a wiring line in the embodiment.

FIGS. 25A and 25B are diagrams showing an example of contact plugs formed on a wiring line by using a conventional method.

FIG. 26 is a diagram showing an example of the latent image formed in a positive resist film through the first exposure process in the embodiment.

FIG. 27 is a diagram showing an example of the latent image formed in the positive resist film through the second exposure process in the embodiment.

FIG. 28 is a diagram showing an example of the hole pattern formed in the positive resist film in the embodiment.

FIG. 29 is a sectional view of an example of a semiconductor memory device formed by the method of the present invention.

FIG. 30 is a sectional view showing an example of capacitor parts of the semiconductor memory device.

FIG. 31 is a perspective view for explaining a conventional example of processing a target film on a substrate by means of known photolithography, in which a mask film and a resist-film pattern are formed on the target film.

FIG. 32 is a perspective view showing a state in which the mask film has been processed so as to form a pattern in the conventional example.

FIG. 33 is a perspective view showing a state in which a resist-film pattern has been formed on the pattern of the mask film.

FIG. 34 is a perspective view showing a state in which the target film has been etched by using the mask-film pattern and the resist-film pattern, and the resist film has been removed.

FIG. 35 is a perspective view showing a state in which hole parts have been formed in the target film.

### DETAILED DESCRIPTION OF THE INVENTION

Hereinafter, embodiments of the present invention will be described with reference to the appended figures. However, the present invention is not limited to the embodiments.

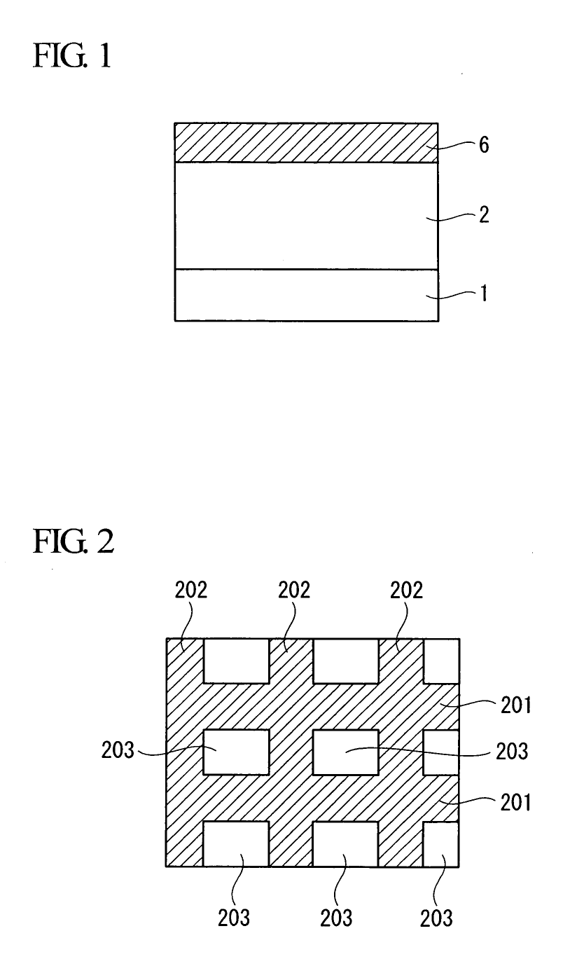

FIGS. 1 to 10 are diagrams used for explaining an example of the method of forming a pattern on an insulating film formed on a substrate in accordance with the present invention. More specifically, an insulating film 2 (i.e., a target film to be processed) made of a silicon oxide film or the like is deposited on a substrate 1 such as an Si wafer, and a positive resist film 6 is stacked thereon.

FIG. 2 is a plan view showing a pattern to be formed. In FIG. 2, reference numerals 203 indicate openings of each hole pattern, and the holes 203 having the same shape are regularly arranged. Reference numerals 201 and 202 indicate resist (film) patterns after the processing as explained later is performed. Although the resist patterns 201 and 202 belong to the same resist film, each line pattern area in the horizontal direction is indicted by the reference numeral 201 and each line pattern area in the vertical direction is indicted by the reference numeral 202, for convenience in the explanations.

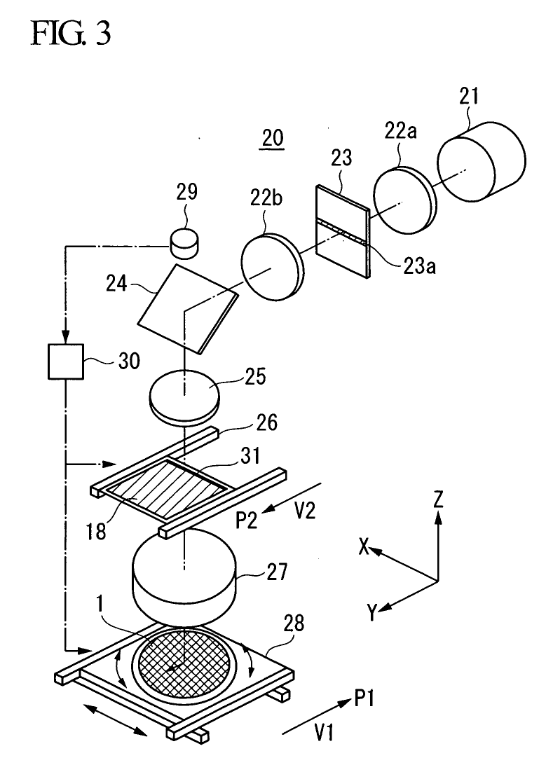

FIG. 3 shows an example of an apparatus used when the resist film 6 is subjected to exposure so as to form a desired pattern.

That is, FIG. 3 shows an example of a projection exposure apparatus for subjecting the substrate 1 (e.g., Si wafer) to exposure. In a projection exposure apparatus 20 in FIG. 3, a light source 21, a lens 22a, a photomask 23, a lens 22b, and a mirror 24 are sequentially aligned along the relevant optical path in the horizontal direction, and below the mirror 24, a condenser lens 25, a photomask stage 26, a projection lens 27, and a stage 28 are also sequentially aligned in the vertical direction. In addition, a control device 30 is connected to the photomask stage 26, the stage 28, and an imaging device 29 arranged in the vicinity of the mirror 24, so as to control the connected elements. On the photomask stage 26, a photomask 18 (i.e., a reticle) is disposed to form a desired pattern. Exposure can be performed by irradiating the substrate 1 with processing light from the light source 21.

As shown in FIG. 4, light from the light source is projected using the projection exposure apparatus 20 (of FIG. 3) onto relevant parts of the resist film 6 via the photomask 18, so as to perform exposure and form each exposed area. Generally, in the photomask, which may be called “reticle”, a wiring line pattern of an electric circuit, a hole pattern for forming a contact hole, or a hole pattern for forming a cylinder hole used for providing a capacitor is formed by using metal, such as chromium, on a transparent glass substrate.

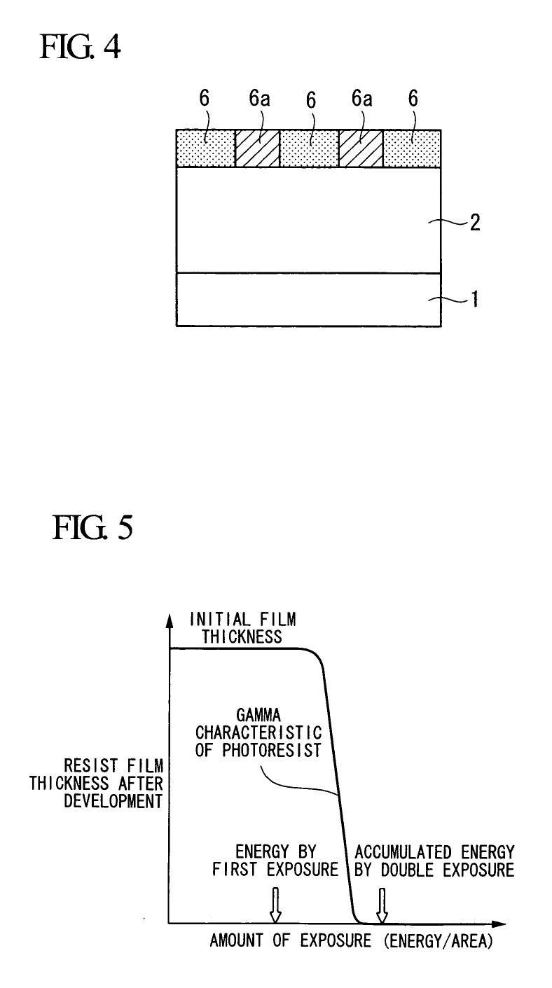

With respect to the exposure of the resist film 6, in order to remove the exposed parts of the resist film 6 in a development process performed after completion of the exposure of the resist film 6 (if the resist film 6 is a positive resist, the exposed parts are removed), a condition (see FIG. 5) with respect to the amount of exposure (i.e., energy/area) should be satisfied.

FIG. 5 shows a relationship between the amount of exposure applied to a positive resist film (which is exposed and then developed) and the thickness of the resist film which remains after the development. As shown in FIG. 5, until the amount of exposure exceeds a specific threshold, there is almost no variation in the thickness of the developed resist film 6. After the amount of exposure exceeds the specific threshold, the thickness of the developed resist film 6 rapidly changes and decreases to zero, that is, the resist film can be removed by means of development.

The resist film 6 used in the present embodiment is not limited to a specific type, and a known positive resist may be used, which may be made of a naphthoquinone diazido-novolac resin, a low-molecular polyphenol resin, a methacrylic resin, an acrylic resin, or the like).

A desired pattern is formed by means of double exposure utilizing the relationship between the amount of exposure and the specific threshold. That is, after a first (projection and) exposure process is performed with an amount of exposure smaller than the threshold, a second (projection and) exposure process is performed so that the sum of the amounts of exposure through the first and second exposure processes slightly exceeds the threshold. The method will be explained in detail below.

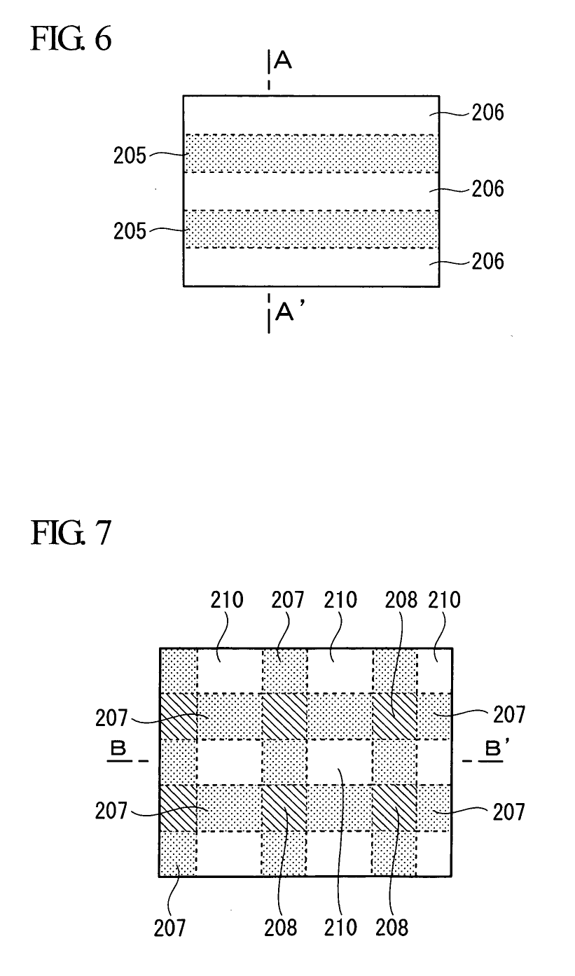

First, by using a photomask having line patterns which block only light corresponding to the line patterns 201 in FIG. 2, the relevant resist film is subjected to a first exposure process, so as to obtain an amount of exposure smaller than the threshold as shown in FIG. 5 (for convenience of the explanation, the amount of exposure is assumed to be 60% of the threshold). FIG. 6 is a plan view after development, and FIG. 4 is a partial sectional view along line A-A′ in FIG. 6.

In FIG. 6, reference numerals 206 indicate areas which were exposed with the amount at 60% of the threshold, and reference numerals 205 indicate areas where light is blocked by the relevant photomask, that is, where the amount of exposure is 0% of the threshold.

In FIG. 6, the set amount of exposure is smaller than the threshold. Therefore, if development is performed in this state, no pattern is formed. However, in the resist film, latent-image patterns 205 and 206 corresponding to the pattern of the photomask used in exposure are formed.

In FIG. 4, reference numerals 6a each indicate a latent-image pattern in an area where the amount of exposure is 0% of the threshold.

In the next step, by using a photomask having a pattern by which only light at the areas corresponding to the vertical line patterns 202 is blocked, the relevant resist film is subjected to a second exposure process, where the amount of exposure is set to be smaller than the threshold (for convenience of the explanation, the amount of exposure is assumed to be 60% of the threshold). In this process, with respect to each area which receives light in both the first and second exposure processes, the amount of exposure is set in a manner such that the total sum of the amounts exceeds the threshold.

FIG. 7 is a plan view obtained immediately after the second exposure process (i.e., before development). The resist film includes (i) areas 208 where the amount of exposure is 0% of the threshold, (ii) areas 207 where the amount of exposure is 60% of the threshold, and (iii) and areas 210 where the amount of exposure is 120% of the threshold.

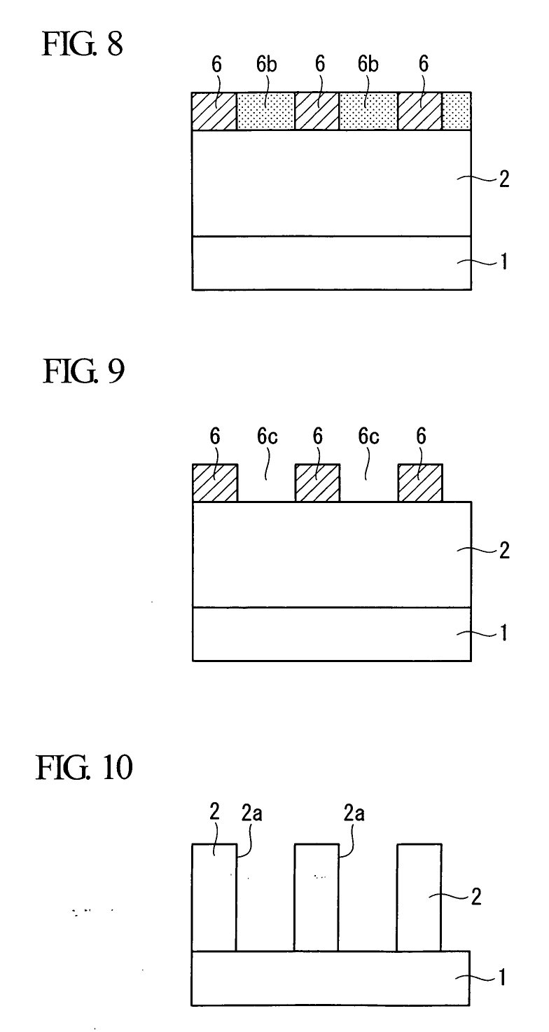

FIG. 8 shows a sectional view along line B-B′ in FIG. 7. In FIG. 8, reference numerals 6 each indicate a latent-image pattern of each area where the amount of exposure is 0% of the threshold, and reference numerals 6b each indicate a latent-image pattern of each area where the amount of exposure is 120% of the threshold.

When subjecting the resist film in this state to development, only each part (in the resist film) where the amount of exposure exceeds the threshold is removed by means of dissolution due to a chemical reaction. That is, in FIG. 7, the resist film is removed only in the areas 210 where the amount of exposure is 120% of the threshold, and in the other areas, no resist film is removed because the amount of exposure does not exceed the threshold.

Therefore, it is possible to form a resist film pattern (i.e., a basic pattern) in which only the parts corresponding to holes (see the openings 203 in FIG. 2) are open.

FIG. 9 is a sectional view along line B-B′ in FIG. 7, observed after the development. In each area 6b in FIG. 8, the amount of exposure is 120% of the threshold. Therefore, this part is removed due to the development, and the part of each area 6 remains. Therefore, as shown in FIG. 9, it is possible to form each basic pattern part 6c used as a standard (having a standard opening dimension) when forming the relevant hole in the target film to be processed. By performing wet or dry etching via the basic pattern parts 6c, a pattern of hole parts 2a (i.e., processed parts) in FIG. 10, which has a desired size, can be formed in the insulating film 2 (i.e., target film). In the present invention, the opening size of each hole can be finely adjusted based on the basic pattern. A specific method thereof will be described later.

With respect to the hole parts 2a, instead of using a photomask which has hole patterns, two photomasks having line patterns whose directions differ from each other are used for performing two exposure processes.

In the conventional techniques, the shape of the corners of each hole is rounded due to diffraction of light at each corner of the corresponding hole in the photomask, and thus it is difficult to accurately process the target in conformity of the relevant photomask. However, in accordance with the method of the present invention, as no corner part is present in the photomask, it is possible to accurately form each hole.

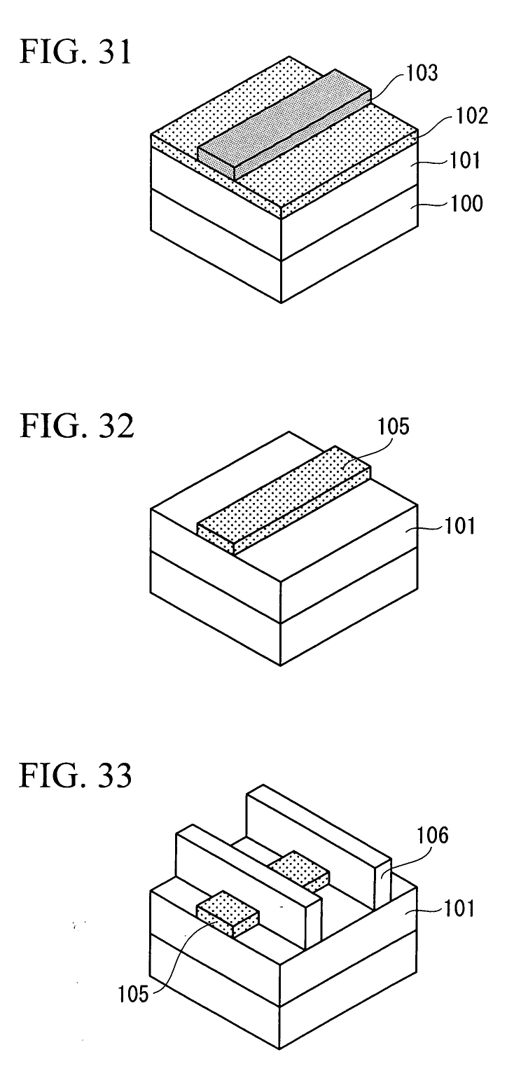

In addition, the resist film should be subjected to only two exposure processes, that is, no complex procedure (as performed in the relevant conventional technique explained with reference to FIGS. 31 to 35) is necessary.

In the above example, the amount of exposures in the first and second exposure processes are each 60% of the threshold. However, the present invention is not limited to such an amount of exposure.

However, if the amount of exposure is excessively increased, thinning of pattern width or the like tends to occur. Therefore, preferably, with respect to the threshold, the amount of exposure in the first process may be within a range of 55 to 70%, and the amount of exposure in the second process may also be within a range of 55 to 70%, so that the total sum of the amounts exceeds 110%.

In FIG. 2, a pattern including holes having a rectangular shape is assumed as the target for double exposure. Therefore, in the above example, two exposure processes are performed respectively using line patterns which are perpendicular to each other in the vertical and horizontal directions. However, the pattern formed in the photomask 18 of the projection exposure apparatus 20 is not limited to such an example, and a target area for double exposure may be determined in conformity of a desired hole pattern (e.g., a hole having a polygonal shape). That is, the shape of the pattern formed in the photomask 18 is not limited to line patterns perpendicular to each other.

In the above embodiment, the hole parts 2a (see FIG. 10) formed in the target film to be processed are provided based on the hole parts 6c formed in the resist film 6 by means of an overlapped pattern including outlines with respect to the above-described different line patterns. Therefore, the outline shape of each corner part can be accurately formed even in a fine photolithography process performed when each side of a hole is shorter than the wavelength of light used in the photolithography, for example, when the outline dimension of each hole part 6c is required to almost correspond to the limit resolution.

In addition, the manner of the exposure in the present invention is not limited to double exposure, and multiple exposure (e.g., triple or quadruple) may be performed. In either case, the resist film is processed in a manner such that parts of the resist film which were subjected to multiple exposure are removed or made to remain after development by means of a combination of exposure processes, each having an amount of exposure smaller than the relevant threshold, and then the target film (under the resist film) to be processed is etched so as to produce a desired form.

Below, another embodiment of the present invention will be shown, in which the thickness of the film to be processed is large, and the resist film has an insufficient tolerance with respect to long-time etching.

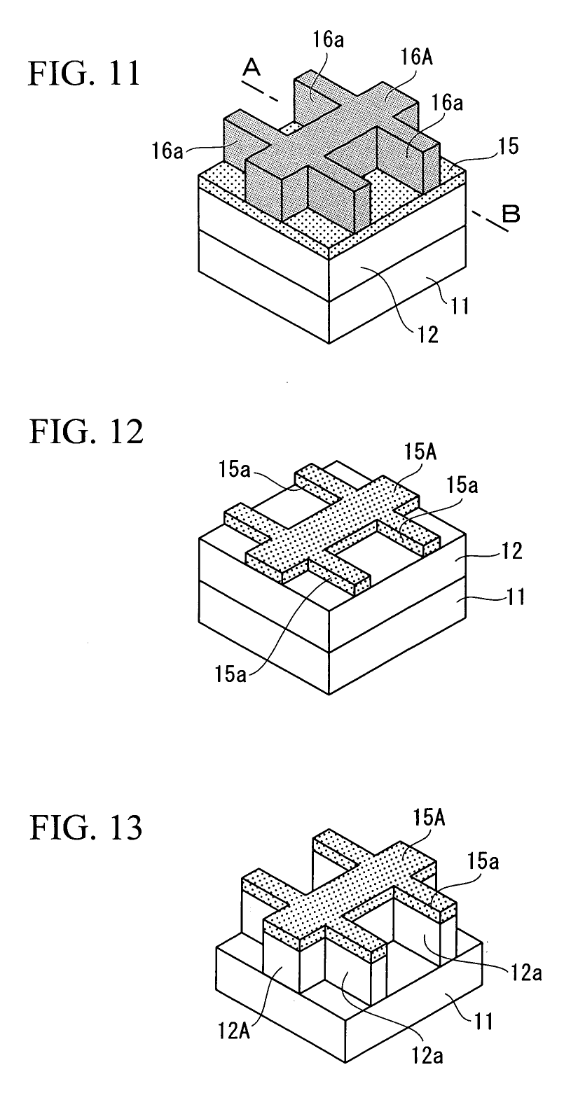

FIGS. 11 to 14 are diagrams for explaining an example of processes, which are performed by applying the present invention to such a target film having a large thickness, so as to form a plurality of holes having a rectangular form (in plan view).

With respect to FIG. 11, an insulating film 12 (i.e., target film to be processed) such as a silicon oxide film is stacked on a substrate 11 such as an Si wafer, and a mask film 15 such as a silicon nitride (Si₃N₄) film is further stacked thereon. A resist film is further stacked thereon, and is subjected to exposure by means of double exposure as explained with reference to FIGS. 1 to 10, and then subjected to development. FIG. 11 shows a state in which a resist film 16A having rectangular holes 16a (i.e., basic pattern parts) is formed after development.

As the hole parts 16a having an accurate form are formed in the resist film 16A due to the above-described double exposure, the corners of each hole part 16a are not rounded but provide an accurate rectangular form even when the hole part 16a has a minute dimension close to the limit resolution with respect to the present photolithography technique. Therefore, it is possible to obtain a target film 12A (to be processed) having the basic pattern part which includes the hole parts 16a having a desired rectangular shape in plan view.

When the mask film 15 as shown in FIG. 11 is etched via the resist film 16A, a mask layer 15A having a basic pattern part which includes hole parts 15a having an accurate rectangular shape can be obtained as shown in FIG. 12.

When patterning of the mask film 15 is completed, the resist film 16A is removed.

When the insulating film 12 is etched via the mask layer 15A, an insulating film 12A including hole parts 12a which have a target rectangular shape (in plan view) can be obtained as shown in FIG. 13.

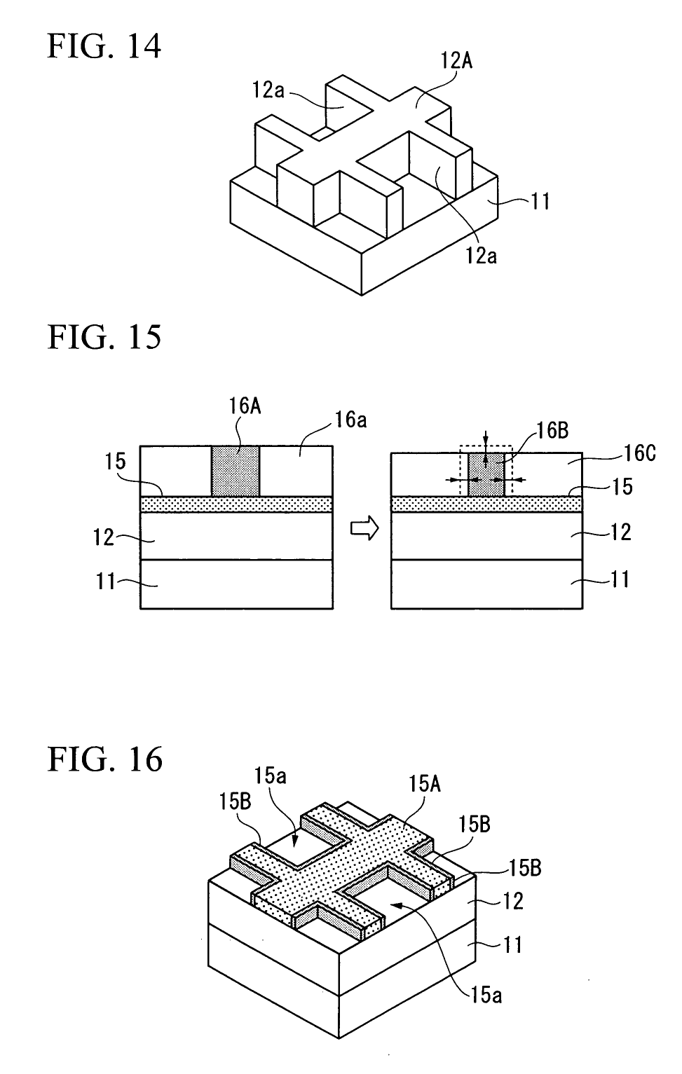

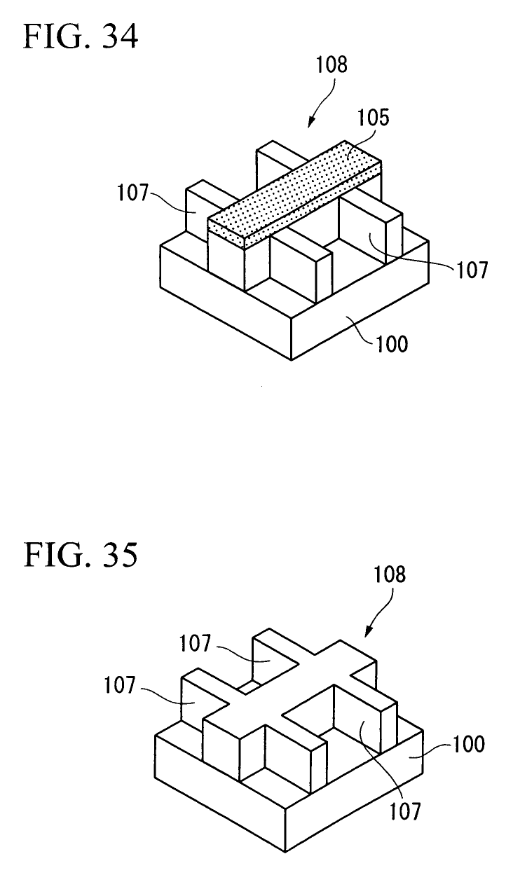

As shown in FIG. 13, the mask layer 15A covers the areas other than the openings of the insulating film 12 by a constant thickness. Therefore, in comparison with the conventional technique as shown in FIG. 34, surface flatness is not damaged. Accordingly, when an insulating material such as a silicon nitride film is used for forming the mask, the mask causes no problem and thus may remain. In addition, if a conductive material such as polysilicon is used as a mask material, then the mask layer 15A is removed by means of etching after the relevant holes are provided. Accordingly, as shown in FIG. 14, the insulating film 12A can be obtained where the hole parts 12a having a rectangular shape in plan view are formed on the substrate 11.

After forming the resist film 16A having the hole parts 16a (see FIG. 11), as shown in FIG. 15 (i.e., sectional view along line A-B in FIG. 11), light ashing (for slightly and isotropically etching an organic film via an O₂ plasma process) may be applied to only the surface area of the resist film 16A, so that the entire surface of the resist film 16A, which is exposed on the insulating film 12, is isotropically processed and thinned, that is, the section of the resist film 16A is thinned. In other words, a resist film 16B having enlarged hole parts 16C transformed from the hole parts 16a of the resist film 16A may be formed, and after that, the target film 12 may be patterned by sequentially performing the processes as shown in FIGS. 12 and 13.

In this example, as the resist film 16A is thinned, larger-sized hole parts 16C can be obtained in comparison with the states shown in FIGS. 13 and 14. Accordingly, the size (i.e., vertical and horizontal widths except for the depth) of each hole part 16C can be easily and accurately adjusted to be slightly larger than that shown in FIG. 13. Also in this case, the above-described double exposure is performed. Therefore, even in photolithography performed at almost the limit resolution, each rectangular hole part 16C is not rounded, and can have a shape which almost corresponds to that of the photomask.

On the other hand, after forming the mask layer 15A having the hole parts 15a (see FIG. 12), as shown in FIG. 16, a side wall 15B made of a silicon oxide film or the like may be attached to each side of the mask layer 15A so as to partially expand the entire sides of the mask layer 15A which is exposed on the insulating film 12, that is, to thicken the section of the mask layer 15A. In other words, the etching process shown by FIGS. 13 and 14 may be performed after the hole parts 15a are narrowed.

In this example, as the mask layer 15A is thickened, smaller-sized hole parts 12a can be obtained in comparison with the state shown in FIG. 14. Accordingly, the size of each hole part 15a can be easily adjusted to be slightly smaller than that shown in FIG. 13.

Generally, when forming a pattern having a size close to the limit resolution of the exposure apparatus, it is known that a line-space ratio of approximately 1:1 in the mask can improve a margin with respect to pattern formation in manufacturing. However, a change in the size of each hole formed in accordance with the above ratio may be desired depending on the structure of a target device to be manufactured. In the present invention, in order to adjust the ratio, the above-described methods can be selectively performed. That is, (i) the method of isotropically thinning the entire surface of the resist film 16A so as to enlarge the hole parts 16a of the resist film 16A and to obtain the resist film 16B having the enlarged hole parts 16C, or (ii) the method of attaching the side walls 15B to the side faces of the mask layer 15A so as to partially expand the entire side faces of the mask layer 15A which is exposed on the insulating film 12 and thus to thicken the section of the mask layer 15A, is selectively utilized so as to form hole patterns which are not restricted by a line-space ratio of approximately 1:1.

That is, in the present invention, after a resist pattern is formed at a dimension corresponding to the basic pattern part, the above-described method may be performed so as to finally adjust the size of each hole, thereby easily obtaining each hole having a desired dimension without rounding each corner thereof.

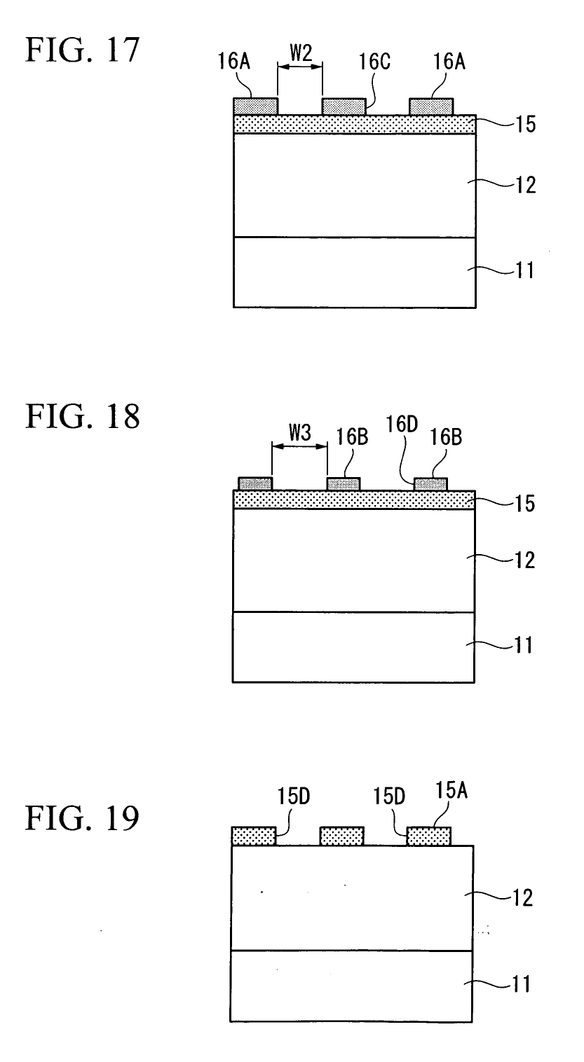

The above-described ashing process (see FIG. 15) for performing isotropic etching via an O₂ plasma process will be further explained with reference to FIGS. 17 to 19. After the resist film 16A is processed and patterned (see FIG. 17), the above ashing is performed so as to thin the section of the resist film 16A (see FIG. 18) in a manner such that the width W2 of each hole part 16C shown in FIG. 17 is increased to the width W3 of each hole part 16D shown in FIG. 18. When the mask film 15 is etched and patterned based on a resist film 16B having the hole parts 16D, a mask layer 15A having a basic pattern part which includes hole parts 15D (see FIG. 19) is obtained. After that, the target film 12 (i.e., insulating film) to be processed is etched using the mask layer 15A, thereby forming hole parts in the target film 12, which have a slightly larger width in comparison with the state shown in FIG. 14.

When increasing the final dimension of the holes as described above, the mask film 15 is not always necessary. That is, no problem occurs when the resist film 16 is directly formed on the insulating film 12.

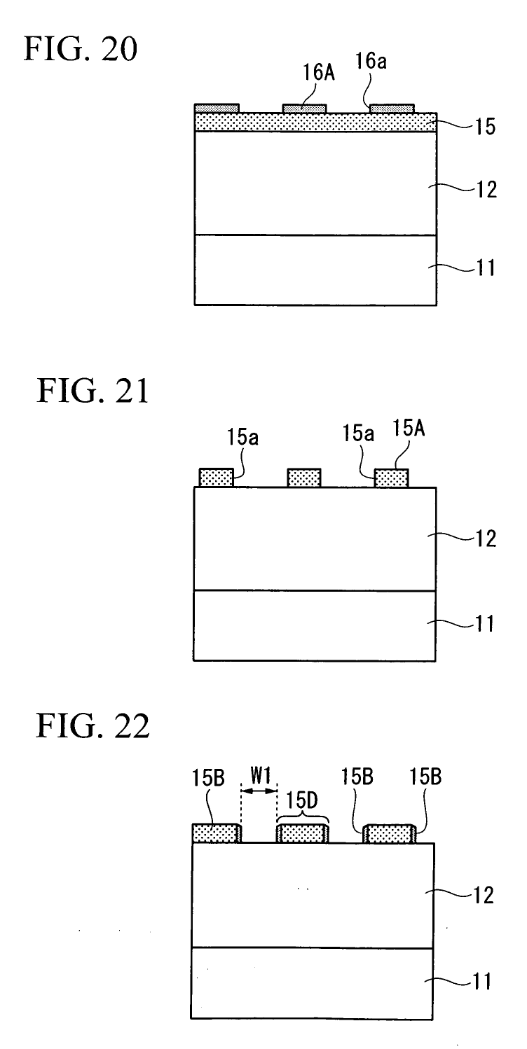

Next, the above-described process for adding the side walls 15B (see FIG. 16) will be further explained with reference to FIGS. 20 to 22. After the resist film 16A is processed and patterned (see FIG. 20), the mask layer 15A is patterned by means of etching (see FIG. 21), and the side walls 15B are added as shown in FIG. 22, thereby reducing the width W1 of the hole parts 15a and forming a basic pattern part in the mask layer 15A. When etching is performed based on a mask film 15D having the side walls 15B, a plurality of hole parts, each having a smaller diameter, or a finer patter can be formed in the target film 12.

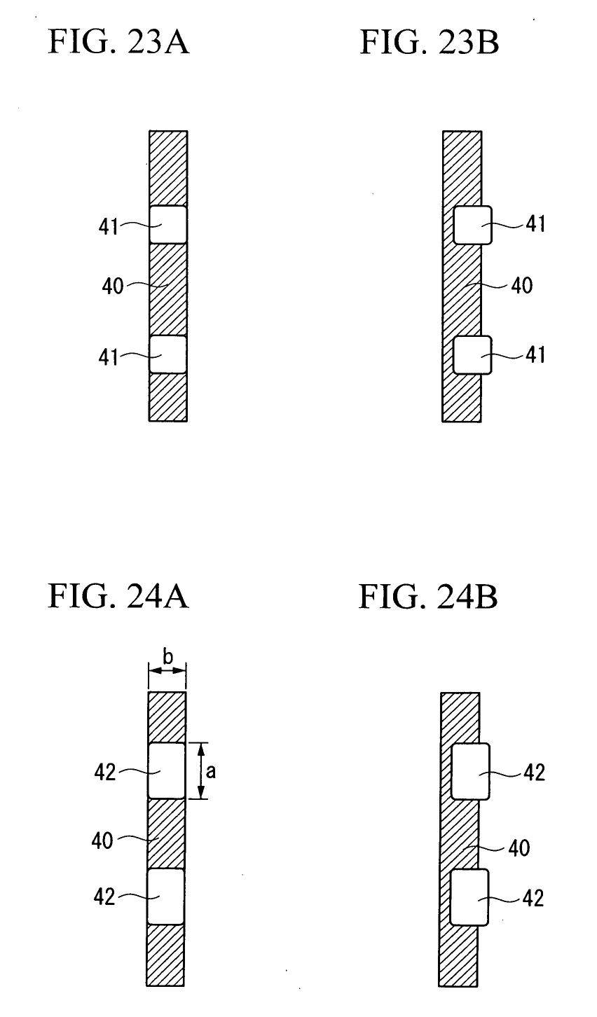

FIG. 23A shows a state in which wiring contact parts 41 (i.e., contact plugs) are formed on a wiring line 41, where each contact part 41 has a square section having the same width as that of the wiring line 40. Although it is not shown in FIG. 23A, an insulating film is formed on the wiring line 40, and contact holes, each having a square section, are formed in the insulating film by means of double exposure as explained above. The wiring contact parts 41 can be formed by embedding a conductive material into each hole.

As described above, in accordance with the present invention, even in an exposure process performed in the vicinity of the limit resolution, the corner outline of a square form (in the relevant cross section) can be accurately developed so as to form contact holes in the relevant insulating film by means of double exposure, and a conductive material can be embedded into the contact holes. Accordingly, as shown in FIG. 23A, the wiring contact parts 41 having a square shape in plan view can be formed.

In addition, if each contact hole formed in the insulating film has a rectangular sectional shape, wiring contact parts 42, each having a rectangular shape (of width “b” and length “a”) having the same width as the wiring line 40, can be formed as shown in FIG. 24A.

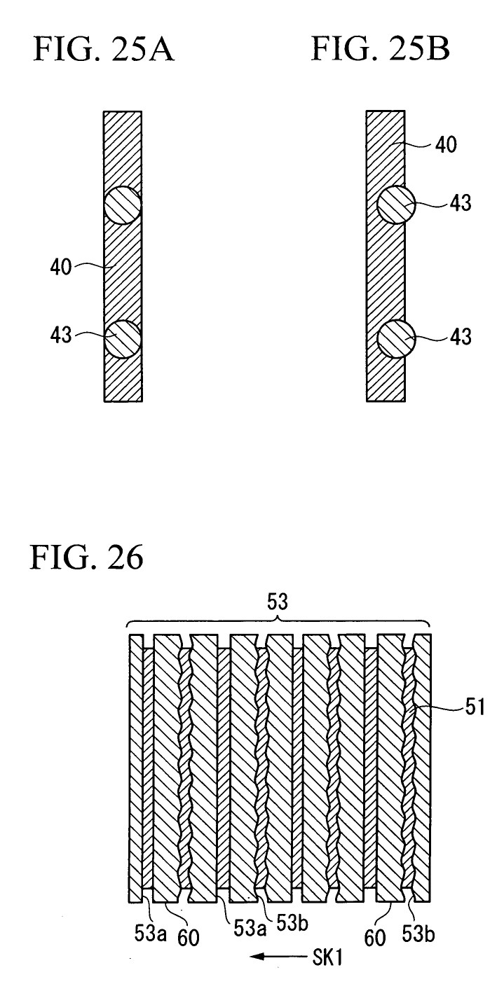

With respect to the above examples, when corresponding wiring contact parts are formed by (i) forming contact holes in a target film to be processed (i.e., an insulating film) by performing a conventional photolithography in which a single projection exposure process having an amount of exposure larger than the threshold is applied to a resist film before development, and (ii) embedding a wiring material into the contact holes after the development, then even if wiring contact parts having a square shape which has the same width as that of the wiring line 40 are desired, wiring contact parts 43 having an almost circular form (see FIG. 25A) are actually formed. This is because even when a projection exposure process which targets a square shape in plan view is applied to the relevant resist film, optical diffraction must occur in the vicinity of each corner of the exposed area in photolithography for performing fine processing in the vicinity of the limit resolution.

When comparing the wiring contact parts 41 in FIG. 23A with the wiring contact parts 43 in FIG. 25A, each wiring contact part 41 formed through double exposure in accordance with the present invention can increase the contact area by 4/π times in comparison with the conventional wiring contact part 43. In addition, the wiring contact parts 42 having a rectangular shape (width “a”×length “b”) as shown in FIG. 24A can further increase the contact area, thereby further reducing the contact resistance between the wiring line 40 and each wiring contact part 42.

Additionally, even if the positions of the wiring contact parts 41, 42, and 43 are offset as respectively shown in FIGS. 23B, 24B, and 25B, the wiring contact parts 41 and 42 having a square or rectangular shape can minimize the corresponding decrease in the contact area with respect to the wiring line.

FIGS. 26 to 28 are diagrams used for explaining an example of the formation of a basic pattern part having a plurality of hole parts 50 (see FIG. 28) by means of double exposure (as explained above) using a positive resist. After a resist film 51 is formed on a substrate by means of spin coating or the like, a first exposure process (with respect to the above-described double exposure) is performed, wherein the amount of exposure is set to be smaller than the threshold assigned to the formed resist film 51 (see a latent-image pattern 53 which is shaded in FIG. 26).

The latent-image pattern 53 in FIG. 26 is an example obtained by exposure using the projection exposure apparatus 20 (see FIG. 3) so as to form a desired pattern on the resist film 51 via the photomask 18. As the latent-image pattern 53 formed through the first exposure process is provided with the smaller amount of exposure than the threshold, the resist film 51 is not patterned even if the resist film 51 is developed. In this example, as shown in FIG. 28, a larger number of the hole parts 50 (i.e., hole patterns), each having a substantially rectangular form (i.e., having four sides), are arranged. Therefore, the latent-image pattern 53 with respect to the first exposure process includes two linear parts 53a and two wavy parts 53b which appear alternately. That is, the first exposure process may be performed by using a photomask for setting the areas other than patterns 60 to be shaded areas. In the present embodiment, in order to form the latent-image pattern 53 (in FIG. 26) through the first exposure process, it is preferable that the scanning direction for performing scanning exposure be set from the right to left side (see the arrow SK1), that is, set to a direction perpendicular to the line parts 53a.

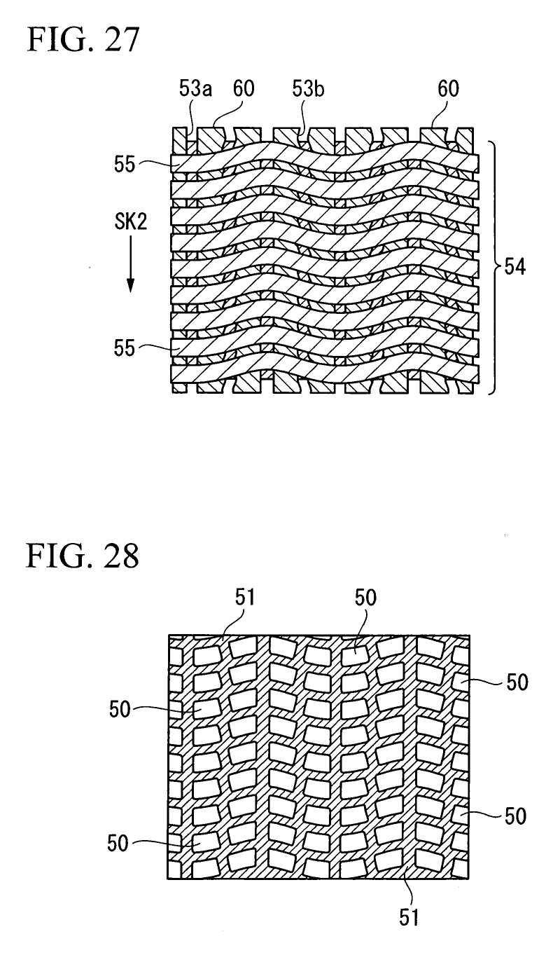

Below, the second exposure process is performed in addition to the above first exposure process. The amount of exposure in the second exposure process is set in a manner such that in each area which is subjected to double exposure, the total sum of the amounts of exposure through the first and second processes slightly exceeds the threshold with respect to the resist film 51. As shown in FIG. 27, a latent-image pattern 54 used in the second exposure process may include wavy strip patterns 55 arranged at regular intervals. That is, the second exposure process may be performed using a photomask for setting the areas other than the patterns 55 to be shaded areas. In the present embodiment, in order to form the latent-image pattern 54 (in FIG. 27) through the second exposure process, it is preferable that the scanning direction for performing scanning exposure be set from the upper to lower side (see the arrow SK2), that is, set to a direction parallel to the line parts 53a. Therefore, the scanning direction in the first exposure process is perpendicular to that of the second exposure process.

The total sum of the amounts of exposure exceeds the threshold with respect to the resist film 51 only in the exposed areas where the latent image of the patterns 60 formed through the first exposure process and the latent image of the patterns 55 formed through the second exposure process superimpose each other. Therefore, when development is performed after the second exposure process, only the areas subjected to double exposure can be removed. Therefore, it is possible to form and arrange a large number of the hole parts 50, each having a substantially rectangular shape (see FIG. 28), thereby forming a basic pattern part.

In accordance with the above double exposure, when forming a fine hole pattern corresponding to almost the limit resolution, a desired rectangular hole pattern (which does not have rounded corners) can be formed. Therefore, by using the resist film having a large number of such hole parts 50, a large number of hole patterns can be formed on a film to be processed (e.g., an insulating film), which is positioned under the resist film.

In addition, the first and second exposure processes may be performed by respectively using photomasks to which different magnification are assigned in the vertical and horizontal directions. As described above, in the present invention, the scanning directions of the first and second processes can be perpendicular to each other. Therefore, in each exposure process, the scanning can be performed in the direction most suitable for the pattern arrangement of the photomask used in the process.

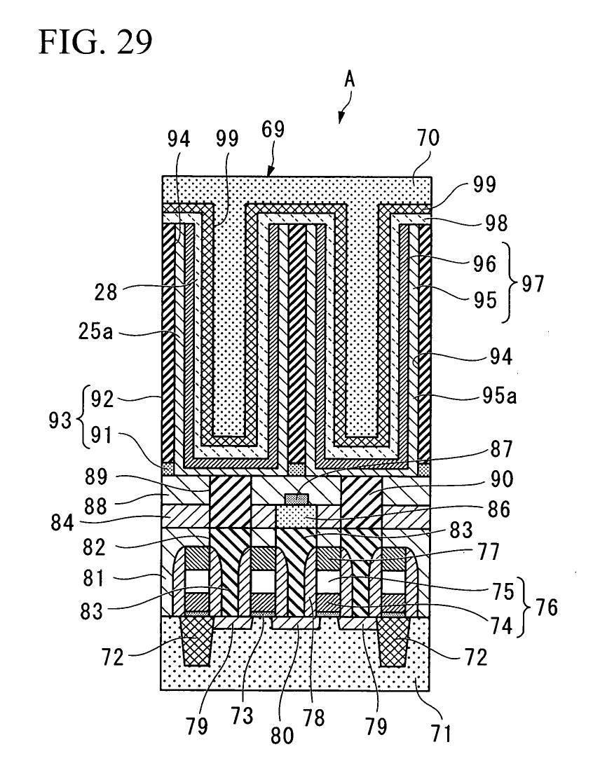

FIG. 29 is a sectional view of an example of a semiconductor memory device formed by the method of the present invention. In a semiconductor memory device A of the example, reference numeral 71 indicates a semiconductor substrate made of a semiconductor (e.g., silicon) including impurities of a specific concentration.

On the semiconductor substrate 71, element separating areas 72 are formed in areas other than transistor formation areas by means of STI (shallow trench isolation), so as to insulate and isolate each transistor (for a selecting function).

In a transistor formation area, each gate insulating film 73 is formed as a silicon oxide film on the semiconductor substrate 71 by means of, for example, thermal oxidation.

Each gate electrode 76 is a multilayer film consisting of a polysilicon film 74 and a metal film 75. As the polysilicon film 74, a doped polysilicon film may be used, which is formed by means of CVD in a manner such that it includes impurities such as phosphorus. The metal film 75 may be formed using a refractory metal (i.e., having a high melting point) such as tungsten (W) or tungsten silicide (WSi).

On each gate electrode 76, that is, on each metal film 75, an insulating film 77 made of silicon nitride (Si₃N₄), and a side wall 78 made of an insulating film (e.g., a silicon nitride film) is provided at the side wall of each gate electrode 76.

The present embodiment employs a cell structure in which 2-bit memory cells are arranged in an active area interposed by the two element separating areas 72 shown in FIG. 29.

In such an active area, impurity diffusion layers are provided at both sides and the center thereof. That is, in the present embodiment, a drain 80 is formed at the center, and sources 79 are provided at both sides in the active area. The gate insulating films 73 which are positioned on and thus contact the sources 79 and the drain 80 form the basic transistor structure, together with the gate electrodes 76 formed on the gate insulating films 73.

On the entire surface of the semiconductor substrate 71 and the insulating films 77, a first inter-layer insulating film 81 is formed by sequentially stacking a BPSG film and a TEOS-NSG film.

In order to expose the sources 79 and the drain 80, a plurality of cell contact holes 82 are provided through the first inter-layer insulating film 81. A polysilicon film having a specific impurity concentration is embedded into each cell contact hole 82, thereby forming each cell contact plug 83.

On the entire surface of the first inter-layer insulating film 81 and the cell contact plugs 83, a second inter-layer insulating film 84 made of a silicon oxide film is formed.

In order to expose the end face of the center cell contact plug 83, a bit contact hole is provided through the second inter-layer insulating film 84. A conductive material is embedded into the bit contact hole so as to form a bit contact plug 86.

On the surface of the bit contact plug 86, a bit wiring layer 87 made of a metal film (e.g. tungsten film) is formed. That is, the bit wiring layer 87 is connected to the diffusion layer as the drain via the bit contact plug 86 and the cell contact plug 83 thereunder.

On the entire surface of the second inter-layer insulating film 84 and the bit wiring layer 87, a third inter-layer insulating film 88 is formed, which is made of a silicon oxide film formed by means of plasma CVD.

In order to expose the end faces of the relevant cell contact plugs 83, capacitance contact holes 89 are provided through the third inter-layer insulating film 88 and the second inter-layer insulating film 84. A polysilicon film having a specific impurity concentration is embedded into each capacitance contact hole 89, thereby forming each capacitance contact plug 90.

A fourth inter-layer insulating film 93 is formed on the third inter-layer insulating film 88 and the capacitance contact plugs 90, and consists of a nitride film 91 and a silicon oxide film 92 which functions as a core of cylinders (explained below). The nitride film 91 is used as an etching stopper when each deep-hole cylinder 94 (for a capacitor) is formed.

At the position where the surface of each capacitance contact plug 90 is exposed, a deep-hole cylinder 94 (cylinder hole) for a capacitor is provided through the fourth inter-layer insulating film 93. At the inner bottom face and inner-peripheral face of each deep-hole cylinder 94, a lower electrode 97 is provided, which is formed by sequentially stacking an impurity-contained silicon film 95 and a lower metal electrode 96.

The impurity-contained silicon film 95 includes a silicide layer 95a at least in the vicinity of the boundary face between the silicon film 95 and the lower metal electrode 96, where the silicide layer 95a is formed by a reaction between silicon and metal which is included in the lower metal electrode 96. As the silicide layer 95a is a low resistance film, electric resistance between a capacitor (explained below) and the corresponding resistance contact plug 90 is reduced.

On the surface of the lower electrodes 97 and the fourth inter-layer insulating film 93, a capacitance insulating film 98 and an upper electrode 99 are sequentially stacked. In addition, a capacitance plate 70 is provided so as to fill the inside of each cylinder surrounded by the upper electrode 99, and be stacked on the upper electrode 99 which is formed on the fourth inter-layer insulating film 93. That is, the lower electrodes 97, the capacitance insulating film 98, the upper electrode 99, and the capacitance plate 70 form capacitors 69 which function as a capacitance storage part for storing data.

In the present embodiment, in order to form the deep-hole cylinders 94 for forming the capacitors 69, the fourth inter-layer insulating film 93 is handled as a target film to be processed, so as to apply the above-described double exposure thereto.

By using the method of the present invention, four-corner form (i.e., square or rectangular) deep-hole cylinders 94 can be formed. Therefore, it is possible to increase the capacitance of each capacitor, which depends on the surface area of the relevant electrodes.

In the present technical situation, the size of each semiconductor memory device has been further decreased and has become finer. Therefore, if performing a single photolithography process having an amount of exposure which exceeds a specific threshold, each deep-hole cylinder 94 should have a circular section even when a four-corner form is desired.

For example, a cylinder of a DRAM having a relatively fine structure has sides whose dimensions are each approximately 50 to 200 nm. Among the presently-available exposure apparatuses (obtained through mass production), an apparatus having an argon-fluorine (ArF) laser as a light source has the shortest wavelength of 193 nm. Therefore, when providing a cylinder opening having such a fine size, the above-described problem due to optical diffraction at exposure occurs.

With respect to this problem, instead of forming the cylinder opening pattern through a single exposure process, the method of the present invention can be used. That is, by using photomasks each having a line-form pattern, the amount of exposure in the first exposure process is set to be smaller than a specific threshold, and the total sum of the amounts of exposure through the two exposure processes is set to be larger than the threshold. Accordingly, even when forming the deep-hole cylinders 94 having a fine size close to the limit resolution, the deep-hole cylinders 94 can each have a rectangular or square form.

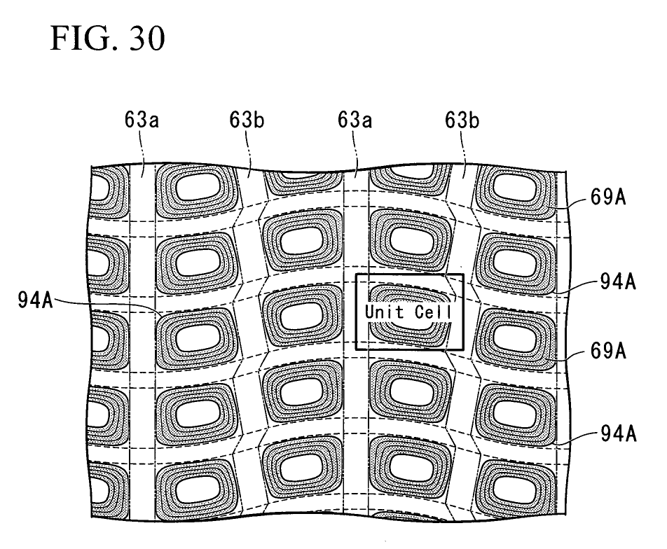

An example thereof is shown in FIG. 30. In this example, by performing the double exposure explained with reference to FIGS. 26 and 27, deep-hole cylinders 94A, each having a substantially rectangular shape (i.e., race-track form), can be formed.

When forming the lower electrodes 97, the capacitance insulating film 98, the upper electrode 99, and the capacitance plate 70 by using the deep-hole cylinders 94A (see FIG. 29), desired capacitors 69A (unit cells) can be formed.

With respect to the capacitors 69A, the corners should be rounded through the conventional technique. However, in accordance with the method of the present invention, each capacitor 69A can have a form close to a target shape (i.e., substantially, a rectangle), as shown in FIG. 30.

In the present embodiment, a double-exposure method in accordance with the present invention is applied so as to form the capacitors 69 of the semiconductor memory device A. However, the target is not limited to the deep-hole cylinders 94A, that is, the double-exposure method can also be applied so as to form any of the cell contact holes 82 formed through the first inter-layer insulating film 81, the bit contact hole provided through the second inter-layer insulating film 84, and the capacitance contact holes 89 provided through the third inter-layer insulating film 88.

When the present invention is applied to forming such an element, the contact plugs 83, 86, and 90 can have a target form. Therefore, in comparison with the conventional structure in which each contact plug has a circular section, each contact plug can have a four-corner (i.e., rectangular or square) section, thereby reducing the contact resistance and improving the transistor characteristics. Accordingly, it is possible to increase the capacity of the semiconductor memory device and also improve the performance thereof.

### CONCRETE EXAMPLES

A concrete example which was actually performed will be described below. In a preparatory process, a transistor structure as shown in FIG. 29 is formed on a semiconductor substrate, and capacitance contact plugs 90 are formed through the second inter-layer insulating film.

In the next step, a silicon nitride film is formed on the second inter-layer insulating film, and a cylinder inter-layer insulating film, which has a thickness of 2500 nm and is made of a silicon oxide film, is further formed thereon.

The cylinder inter-layer insulating film is formed by means of a PECVD (plasma-enhanced CVD) method using monosilane (SiH₄) and nitrogen monoxide (N₂O), or may be formed by a PECVD method using TEOS (Si(OC₂H₅)₄) and oxygen (O₂).

Next, deep-hole cylinders, each passing through the cylinder inter-layer insulating film and the silicon nitride film, are provided by means of photolithography and dry etching, so that the surface of each capacitance contact plug is exposed at the bottom of the relevant deep-hole cylinder.

In this process, when forming the deep-hole cylinders passing through the cylinder inter-layer insulating film and the silicon nitride film, a positive resist film (for ArF) is formed on the relevant insulating film, the amount of exposure in the first exposure process is set to be 65% of the threshold with respect to the resist film, and light having a wavelength of 193 nm is emitted from a light source (i.e., ArF excimer laser) so as to perform exposure utilizing a first latent-image pattern as shown in FIG. 26.

Next, exposure is again performed with the amount of exposure also set to be 65% of the threshold, by utilizing a second latent-image pattern having a form as shown in FIG. 27.

In the deep-hole cylinders formed through the above processes, (i) a multilayer film (i.e., lower-electrode film) consisting of a polysilicon film and a titanium oxide film, (ii) an aluminium oxide film (i.e., capacitance insulating film), and (iii) a titanium nitride film (i.e., upper-electrode film) are formed so as to provide desired cylinders.

FIG. 30 is a schematic diagram showing the sectional shape of each cylinder along the direction parallel to the semiconductor substrate. As shown in FIG. 30, in the concrete example, each cylinder structure having a form close to a substantial rectangle can be formed in the relevant inter-layer insulating film. Here, the provided rectangular form is closer to a rectangle than a so-called “race-track form”.

In the structure shown in FIG. 30, the longer and shorter sides of each cylinder having a substantially rectangular section are respectively 150 nm and 70 nm.

In accordance with the present invention, a fine deep-hole cylinder having a dimension such as 150 nm×70 nm in the cross section, that is, a section form close to a rectangle (in the cross section), can be formed in a target insulating film by performing a double-exposure method as described above.

As a comparative example which was also performed, deep-hole cylinders having a similar size are formed in a resist film, which has a material similar to the above, through a single exposure process, and then the second inter-layer insulating film is etched. As a result, instead of the form as shown in FIG. 3, each deep-hole cylinder has a section close to an ellipse.

While preferred embodiments of the invention have been described and illustrated above, it should be understood that these are exemplary embodiments of the invention and are not to be considered as limiting. Additions, omissions, substitutions, and other modifications can be made without departing from the scope of the present invention. Accordingly, the invention is not to be considered as being limited by the foregoing description, and is only limited by the scope of the appended claims.

1. A pattern forming method comprising the steps of:
forming a resist film on a target film to be processed, which is formed on a substrate;
forming a basic pattern part in the resist film by multiple exposure using photomasks, wherein:
each exposure process is performed at an amount of exposure smaller than a threshold assigned to the resist film; and
the resist film is developed after the total sum of the amounts of exposure through a plurality of exposure processes exceeds the threshold, so that the basic pattern part including a hole shape, which corresponds to each area where the total amount of exposure through the exposure processes via the photomasks exceeds the threshold, is formed in the resist film; and
performing etching via the basic pattern part so as to form a desired pattern in the target film.

2. A pattern forming method comprising the steps of:
sequentially forming a mask film and a resist film on a target film to be processed, which is formed on a substrate;
forming a basic pattern part in the resist film by multiple exposure using photomasks, wherein:
each exposure process is performed at an amount of exposure smaller than a threshold assigned to the resist film; and
the resist film is developed after the total sum of the amounts of exposure through a plurality of exposure processes exceeds the threshold, so that the basic pattern part including a hole shape, which corresponds to each area where the total amount of exposure through the exposure processes via the photomasks exceeds the threshold, is formed in the resist film;
etching the mask film via the basic pattern part so as to form the corresponding basic pattern part in the mask film;
forming a reduced pattern part by providing a side wall to the inside of a hole in the basic pattern part of the mask film so as to narrow the hole; and
etching the target film by using the reduced pattern part.

3. A pattern forming method comprising the steps of:
forming a resist film on a target film to be processed, which is formed on a substrate;
forming a basic pattern part in the resist film by multiple exposure using photomasks, wherein:
each exposure process is performed at an amount of exposure smaller than a threshold assigned to the resist film; and
the resist film is developed after the total sum of the amounts of exposure through a plurality of exposure processes exceeds the threshold, so that the basic pattern part including a hole shape, which corresponds to each area where the total amount of exposure through the exposure processes via the photomasks exceeds the threshold, is formed in the resist film;
forming an enlarged pattern part by partially removing the resist film so as to enlarge a hole in the basic pattern part; and
etching the target film by using the enlarged pattern part.

4. The pattern forming method in accordance with claim 1, wherein double exposure is performed in which:
a first exposure process is performed using a first photomask having a first pattern, where the amount of exposure is set to be smaller than the threshold assigned to the resist film; and
a second exposure process is performed using a second photomask having a second pattern, where the amount of exposure is set to be smaller than the threshold assigned to the resist film, and the total sum of the amounts of exposure through the first and second exposure processes exceeds the threshold.

5. The pattern forming method in accordance with claim 1, wherein the resist film comprises a positive resist film.

6. The pattern forming method in accordance with claim 1, wherein the plurality of exposure processes use different photomasks having patterns which differ from each other, and the total sum of the amounts of exposure through the first and second exposure processes exceeds the threshold in common parts between the patterns of the photomasks.

7. The pattern forming method in accordance with claim 3, wherein when forming the enlarged pattern part, the basic pattern part is subjected to ashing so as to partially remove the basic pattern part.

8. The pattern forming method in accordance with claim 1, wherein reticles to which different magnification are assigned in the vertical and horizontal directions are used as the photomasks.

9. The pattern forming method in accordance with claim 1, wherein when forming the basic pattern part by multiple exposure, the scanning direction of an exposure process is set to be substantially perpendicular to that of another exposure process.

10. The pattern forming method in accordance with claim 2, wherein double exposure is performed in which:
a first exposure process is performed using a first photomask having a first pattern, where the amount of exposure is set to be smaller than the threshold assigned to the resist film; and
a second exposure process is performed using a second photomask having a second pattern, where the amount of exposure is set to be smaller than the threshold assigned to the resist film, and the total sum of the amounts of exposure through the first and second exposure processes exceeds the threshold.

11. The pattern forming method in accordance with claim 3, wherein double exposure is performed in which:
a first exposure process is performed using a first photomask having a first pattern, where the amount of exposure is set to be smaller than the threshold assigned to the resist film; and
a second exposure process is performed using a second photomask having a second pattern, where the amount of exposure is set to be smaller than the threshold assigned to the resist film, and the total sum of the amounts of exposure through the first and second exposure processes exceeds the threshold.

12. The pattern forming method in accordance with claim 2, wherein the resist film comprises a positive resist film.

13. The pattern forming method in accordance with claim 3, wherein the resist film comprises a positive resist film.

14. The pattern forming method in accordance with claim 2, wherein the plurality of exposure processes use different photomasks having patterns which differ from each other, and the total sum of the amounts of exposure through the first and second exposure processes exceeds the threshold in common parts between the patterns of the photomasks.

15. The pattern forming method in accordance with claim 3, wherein the plurality of exposure processes use different photomasks having patterns which differ from each other, and the total sum of the amounts of exposure through the first and second exposure processes exceeds the threshold in common parts between the patterns of the photomasks.

16. The pattern forming method in accordance with claim 2, wherein reticles to which different magnification are assigned in the vertical and horizontal directions are used as the photomasks.

17. The pattern forming method in accordance with claim 3, wherein reticles to which different magnification are assigned in the vertical and horizontal directions are used as the photomasks.

18. The pattern forming method in accordance with claim 2, wherein when forming the basic pattern part by multiple exposure, the scanning direction of an exposure process is set to be substantially perpendicular to that of another exposure process.

19. The pattern forming method in accordance with claim 3, wherein when forming the basic pattern part by multiple exposure, the scanning direction of an exposure process is set to be substantially perpendicular to that of another exposure process.
